(19) United States
(12) Patent Application Publication
(10) Pub. No.: US 2025/0210462 A1
(43) Pub. Date: Jun. 26, 2025

(54) THROUGH SILICON VIA

(71) Applicant: Taiwan Semiconductor Manufacturing Company, Ltd., Hsinchu (TW)

(72) Inventors: Ke-Gang Wen, Hsinchu County (TW); Yu-Bey Wu, Hsinchu (TW); Hsin-Feng Chen, Yilan City (TW); Tsung-Chieh Hsiao, Changhua County (TW); Chih-Pin Chiu, Hsinchu (TW); Liang-Wei Wang, Hsinchu City (TW)

(21) Appl. No.: 18/620,624

(22) Filed: Mar. 28, 2024

Related U.S. Application Data
(60) Provisional application No. 63/612,852, filed on Dec. 20, 2023.

(51) Int. Cl. H01L 23/48; H01L 21/768

(52) U.S. Cl. CPC H01L 23/481; H01L 21/76898

(57) ABSTRACT

A structure according to the present disclosure includes a bottom metal feature, a semiconductor substrate disposed over the bottom metal feature, an interconnect structure disposed over the semiconductor substrate, a top metal feature over the interconnect structure, a via structure extending from a bottom surface of the top metal feature, through the interconnect structure and the semiconductor substrate, to contact a top surface of the bottom metal feature. The via structure includes a bottom portion disposed in the semiconductor substrate and a top portion disposed in the interconnect structure. The bottom portion and the top portion taper toward the top metal feature. The bottom portion includes a first tapering angle and the top portion includes a second tapering angle smaller than the first tapering angle.

### PRIORITY DATA

This application claims the benefit of U.S. Provisional Application No. 63/612,852, filed Dec. 20, 2023, which is hereby incorporated by reference in its entirety.

### BACKGROUND

The integrated circuit (IC) industry has experienced exponential growth. Technological advances in IC materials and design have produced generations of ICs, where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

Besides smaller device dimensions in each generation, packaging technologies have evolved to further boost performance of IC devices. For example, three-dimensional (3D) packaging techniques are introduced to stack multiple IC devices vertically. Through substrate vias (TSVs) are commonly used in 3D device packages because they are configured to route electrical signal from one side of a silicon substrate of an IC chip to the other side thereof.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a flow chart illustrating an embodiment of a method of forming a device structure and a via structure through the device structure, according to various aspects of the present disclosure.

FIGS. 2-17 are fragmentary cross-sectional views of a WIP structure undergoing operations of the method in FIG. 1, according to various aspects of the present disclosure.

FIG. 18-20 illustrate fragmentary cross-sectional views of device structures according to various alternative embodiments of the present disclosure.

FIGS. 21 and 22 illustrate fragmentary cross-sectional views of IC device packages that includes via structures according to the present disclosure, according to various aspects of the present disclosure.

### DETAILED DESCRIPTION

The present disclosure relates generally to integrated circuit devices, and more particularly, to interconnect structures for integrated circuit devices.

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

An interconnect structure electrically couples various components (for example, transistors, resistors, capacitors, and/or inductors) fabricated on a substrate, such that the various components can operate as specified by design requirements. An interconnect structure includes a combination of dielectric layers and conductive layers configured to provide electrical signal routing. The conductive layers include via and contact features that provide vertical connections and conductive lines that provide horizontal connections. In some implementations, an interconnect structure may have eight (8) to twenty (20) levels of metal layers (or metallization layers) that are vertically interconnected by via or contact features. The interconnect structure routes signals among the components of the IC device and/or distribute signals (for example, clock signals, voltage signals, and/or ground signals) to the components. To allow vertical stacking of multiple IC chips in 3D packaging, it is desirable to provide a vertical interconnect that extends through the interconnect structure and/or the substrate to facilitate various device structures. Such a vertical interconnect may be referred to as a through-silicon or through-substrate via (TSV) as it extends through, in whole or in part, the semiconductor substrate. The term TSV in the present disclosure broadly encompasses via structures that provide direct signal routing from a frontside of the substrate and a backside of the substrate or vice versa.

As IC devices are getting increasingly complicated and the interconnect structure includes more and more metallization layers, TSVs may have high aspect ratios. Resistance associated with high-aspect-ratio TSVs may start to play a role in device performance. Conceptually, resistance associated with TSVs may be reduced by increasing dimensions of the TSVs or adopting more electrically conductive materials. Both routes are met with challenges. For example, TSVs and protective structures around TSVs are competing with functional devices and routing metal features for space. Increasing dimensions of TSVs may displace functional devices and reduce device performance. Additionally, some existing TSVs are already formed of sufficiently electrically conductive materials.

The present disclosure provides a TSV structure with a reduced overall resistance. An example TSV according to the present disclosure extends through a semiconductor substrate and an interconnect structure disposed over the semiconductor substrate. The example TSV includes a first portion in the semiconductor substrate and a second portion in the interconnect structure. The first portion tapers toward the interconnect structure and the second portion tapers away from the semiconductor substrate. While the first portion and the second portion tapers along the same direction, the first portion tapers at a greater taper angle than the second portion. In other words, the TSV widens in the semiconductor substrate. The wider first portion allows the TSV to have a reduced contact resistance without interfering with active devices formed on the semiconductor substrate.

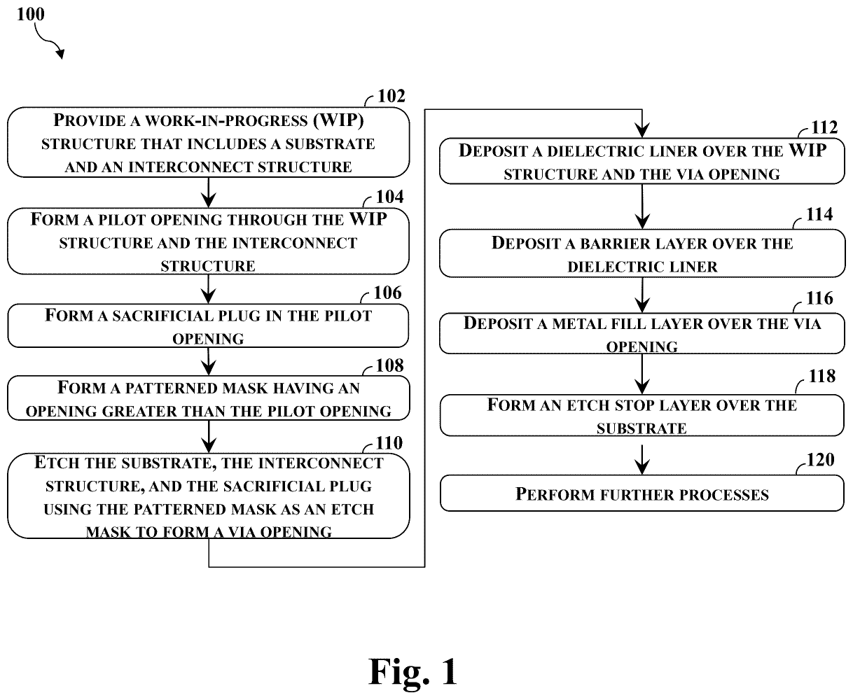

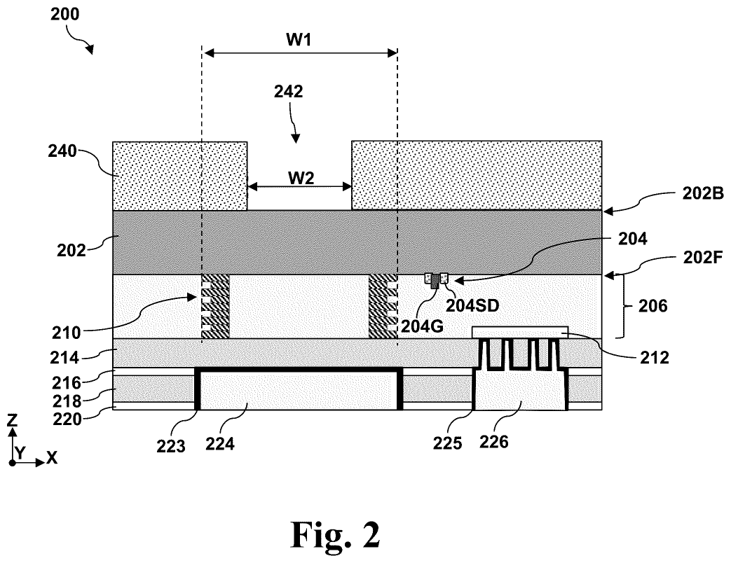

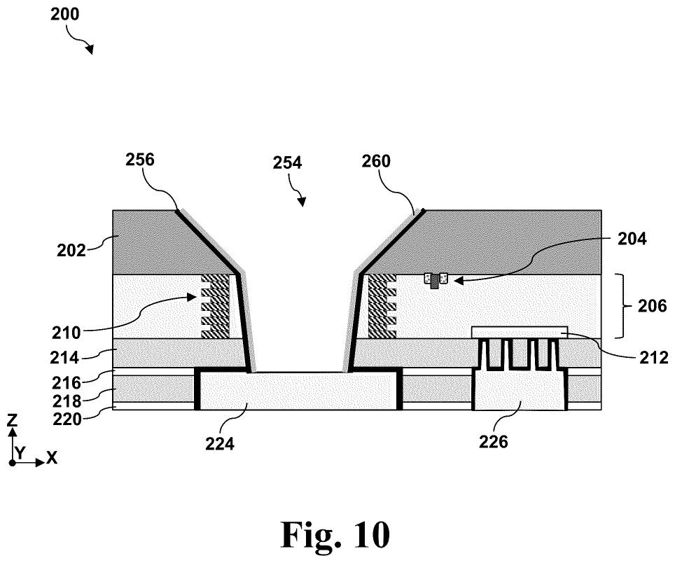

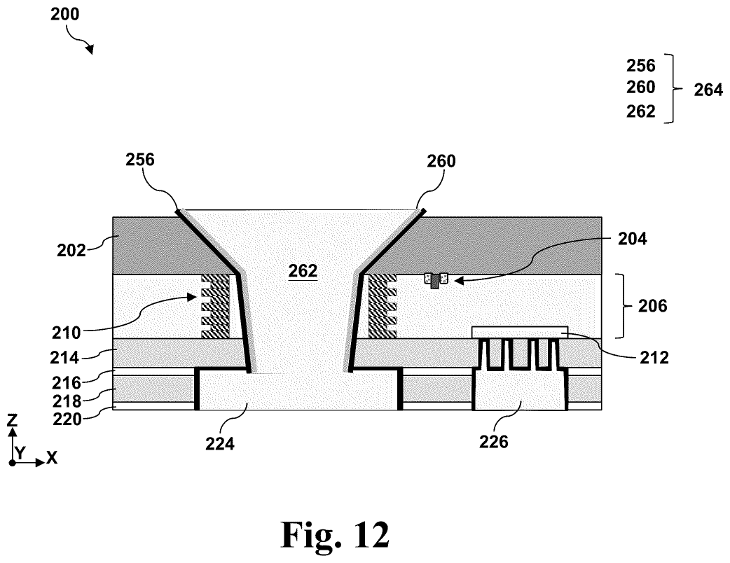

The various aspects of the present disclosure will now be described in more detail with reference to the figures. In that regard, FIG. 1 is a flowchart illustrating a method 100 of forming a contact structure on a work-in-progress (WIP) structure 200 (shown in FIGS. 2-17), according to various aspects of the present disclosure. Method 100 is merely an example and is not intended to limit the present disclosure to what is explicitly illustrated in method 100. Additional steps can be provided before, during and after method 100, and some steps described can be replaced, eliminated, or moved around for additional embodiments of the method. Not all steps are described herein in detail for reasons of simplicity. Method 100 is described below in conjunction with FIG. 2-17, which are fragmentary cross-sectional views of the WIP structure 200 at different stages of fabrication according to various embodiments of method 100. Because the WIP structure 200 will be fabricated into a die, the WIP structure 200 may be referred to herein as a die 200 as the context requires. For avoidance of doubts, the X, Y and Z directions in FIGS. 2-20 are perpendicular to one another. Throughout the present disclosure, unless expressly otherwise described, like reference numerals denote like features.

Referring to FIGS. 1 and 2, method 100 includes a block 102 where a WIP structure 200 is provided. Referring to FIG. 2, the WIP structure 200 includes a substrate 202 and an interconnect structure 206. The substrate 202 includes a front side 202F and a back side 202B. The interconnect structure 206 is disposed over the front side 202F of the substrate 202. In one embodiment, the substrate 202 is a semiconductor substrate formed of silicon (Si). Alternatively or additionally, the substrate 202 may include another elementary semiconductor, such as germanium (Ge); a compound semiconductor, such as silicon carbide (SiC), gallium arsenide (GaAs), gallium phosphide (GaP), indium phosphide (InP), indium arsenide (InAs), and/or indium antimonide; an alloy semiconductor, such as silicon germanium (SiGe), GaAsP, AlInAs, AlGaAs, GaInAs, GaInP, and/or GaInAsP; or combinations thereof. Alternatively, the substrate 202 may be a semiconductor-on-insulator substrate, such as a silicon-on-insulator (SOI) substrate, a silicon germanium-on-insulator (SGOI) substrate, or a germanium-on-insulator (GeOI) substrate. Semiconductor-on-insulator substrates can be fabricated using separation by implantation of oxygen (SIMOX), wafer bonding, and/or other suitable methods. The substrate 202 can include various doped regions (not shown) depending on design requirements of the die 200. In some implementations, the substrate 202 includes p-type doped regions (for example, p-type wells) doped with p-type dopants, such as boron (for example, BF₂), other p-type dopant, or combinations thereof. In some implementations, substrate 202 includes n-type doped regions (for example, n-type wells) doped with n-type dopants, such as phosphorus (P), arsenic (As), other n-type dopant, or combinations thereof. In some implementations, the substrate 202 includes doped regions formed with a combination of p-type dopants and n-type dopants. The various doped regions can be formed directly on and/or in the substrate 202, for example, providing a p-well structure, an n-well structure, a dual-well structure, a raised structure, or combinations thereof. An ion implantation process, a diffusion process, and/or other suitable doping process can be performed to form the various doped regions. In some embodiments, the substrate 202 in the WIP structure 200 may have a thickness between about 5 μm and about 60 μm. It is noted that the substrate 202 may have a much greater thickness (i.e., between about 750 μm and about 800 μm) when the WIP structure 200 is first formed. To accommodate the formation of the via structure, the substrate 202 is thinned to the thickness between about 5 μm and about 60 μm.

Multiple transistors are formed over the front side 202F. A transistor 204 is illustrated in FIG. 2 to represent the multiple transistors for the sake of simplicity. The transistor 204 may be a planar transistor or a multi-gate transistor, such as a fin-like FET (FinFET) or a gate-all-around (GAA) transistor. A GAA transistor may include channel regions of various shapes including nanowire, nanobar, or nanosheet, which may be collectively referred to as nanostructures. A GAA transistor may also be referred to as a multi-bridge-channel (MBC) transistor or a surrounding-gate-transistor (SGT). The transistor 204 representatively shown in FIG. 2 is a FinFET that includes a gate structure 204G wrapping over a channel region of a fin structure (not explicitly shown in FIG. 2) arising from the substrate 202 and source/drain features 204SD disposed over source/drain regions of the fin structure. The fin structure may be formed from the substrate 202, which may be a silicon (Si) substrate, or from an epitaxial layer formed on the substrate 202. While the transistor 204 is shown as a FinFET in FIG. 2 and subsequent figures, it should be understood that the transistor 204 may as well be a planar device or a GAA transistor.

While not explicitly shown, the gate structure 204G includes an interfacial layer interfacing the fin structure, a gate dielectric layer over the interfacial layer, and a gate electrode layer over the gate dielectric layer. The interfacial layer may include a dielectric material such as silicon oxide, hafnium silicate, or silicon oxynitride. The interfacial layer may be formed by chemical oxidation, thermal oxidation, atomic layer deposition (ALD), chemical vapor deposition (CVD), and/or other suitable method. The gate dielectric layer may include a high-k dielectric material, such as hafnium oxide. Alternatively, the gate dielectric layer may include other high-K dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), SrTiO₃ (STO), BaTiO₃ (BTO), BaZrO, hafnium lanthanum oxide (HfLaO), lanthanum silicon oxide (LaSiO), aluminum silicon oxide (AlSiO), hafnium tantalum oxide (HfTaO), hafnium titanium oxide (HfTiO), (Ba,Sr)TiO₃ (BST), silicon nitride (SiN), silicon oxynitride (SiON), combinations thereof, or other suitable material. The gate dielectric layer may be formed by ALD, physical vapor deposition (PVD), CVD, oxidation, and/or other suitable methods.

The gate electrode layer of the gate structure 204G may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof.

The source/drain features 204SD may be deposited using vapor-phase epitaxy (VPE), ultra-high vacuum CVD (UHV-CVD), molecular beam epitaxy (MBE), and/or other suitable processes. When the source/drain features 204SD are n-type, it may include silicon (Si) doped with an n-type dopant, such as phosphorus (P) or arsenic (As). When the source/drain features 204SD are p-type, it may include silicon germanium (SiGe) doped with a p-type dopant, such as boron (B) or boron difluoride (BF₂). In some alternative embodiments not explicitly shown in the figures, the source/drain features 204SD may include multiple layers. In one example, a source/drain features 204SD may include a lightly doped first epitaxial layer over source/drain region of the fin structure, a heavily doped second epitaxial layer over the lightly doped first epitaxial layer, and a capping epitaxial layer disposed over the heavily doped second epitaxial layer. The first epitaxial layer has a lower dopant concentration or a smaller germanium content (when germanium is present) than the second epitaxial layer to reduce lattice mismatch defects. The second epitaxial layer has the highest dopant concentration or the highest germanium content (when germanium is present) to reduce resistance and increase strain on the channels. The capping epitaxial layer may have a smaller dopant concentration and germanium content (when germanium is present) than the second epitaxial layer to increase etching resistance.

The interconnect structure 206 may include eight (8) to twenty (20) metal layers. Each of the metal layers includes an etch stop layer (ESL) and an intermetal dielectric (IMD) layer disposed on the ESL. The ESLs may share the same composition and may include silicon nitride or silicon oxynitride. The IMD layers may share the same composition and may include silicon oxide, tetraethylorthosilicate (TEOS) oxide, un-doped silicate glass (USG), or doped silicon oxide such as borophosphosilicate glass (BPSG), fused silicate glass (FSG), phosphosilicate glass (PSG), boron doped silicate glass (BSG), low-k dielectric material, other suitable dielectric material, or combinations thereof. Example low-k dielectric materials include carbon doped silicon oxide, Xerogel, Acrogel, amorphous fluorinated carbon, benzocyclobutene (BCB), or polyimide. In some embodiments, the interconnect structure 206 in the WIP structure 200 may have a thickness between about 0.5 μm and about 3.5 μm.

Each of the metal layers in the interconnect structure 206 includes a plurality of vertically extending vias and horizontally metal lines. The vias and metal lines functionally connect the multiple transistors, such as the transistor 204, on the substrate 202. Besides the vias and metal lines, the interconnect structure 206 also includes a guard ring structure 210. In some embodiments represented in FIG. 2, the guard ring structure 210 includes a plurality of ring layers in the metal layers. Each of the plurality of ring layers includes a lower portion and an upper portion disposed over the lower portion. As used herein, a ring refers to a structure that extends continuously around a space to form a closed loop. As shown in FIG. 2, each of the plurality of ring layers is a closed loop on the X-Y plane and the plurality of the ring layers are vertically stacked to define a via penetration space in the interconnect structure 206. To prevent metal contamination during formation of a pilot opening or a via opening through the via penetration space, the via penetration space is free of metal. In one embodiment, the guard ring structure 210 has a circular shape when viewed along the Z direction. In some alternative embodiments, the guard ring structure 210 may be rectangular, square, hexagonal, octagonal, or other polygonal shape when viewed along the Z direction. In the depicted embodiment, the guard ring structure 210 includes a first width W1. When the guard ring structure 210 is circular, the first width W1 represents an external diameter of the guard ring structure 210.

In some embodiments represented in FIG. 2, the guard ring structure 210 has a smooth inner wall. This arrangement is not trivial. It is observed that any protrusions or recesses in the inner wall of the guard ring structure 210 may enhance the stress acting on the guard ring structure 210 or the structures adjacent and outside the guard ring structure 210. Vias, metal lines, and the guard ring structure 210 in the interconnect structure 206 may include titanium (Ti), ruthenium (Ru), nickel (Ni), cobalt (Co), copper (Cu), molybdenum (Mo), tungsten (W), aluminum (Al), and/or other suitable materials. In one embodiment, they may include copper (Cu). In some embodiments, in order to prevent electromigration from the metal material or oxygen diffusion from the dielectric features into the metal material, vias, metal lines, and ring layers may each include a barrier layer to interface the ESLs and IMD layers.

In some embodiments represented in FIG. 2, the WIP structure 200 further includes a first passivation layer 214, a first ESL 216 over the first passivation layer 214, a second passivation layer 218, and a second ESL 220 over the second passivation layer 218. In some embodiments, the first passivation layer 214 and the second passivation layer 218 may include silicon oxide, tetraethylorthosilicate (TEOS) oxide, un-doped silicate glass (USG), or doped silicon oxide such as borophosphosilicate glass (BPSG), fused silicate glass (FSG), phosphosilicate glass (PSG), boron doped silicate glass (BSG), low-k dielectric material, other suitable dielectric material, or combinations thereof. The first ESL 216 and the second ESL 220 may include silicon nitride or silicon oxynitride. In some implementations represented in FIG. 2, the WIP structure 200 includes a first top metal feature 224 and a second top metal feature 226 disposed in the first ESL 216, the second passivation layer 218, and the second ESL 220. In some instances, the first top metal feature 224 and the second top metal feature 226 may include copper (Cu), aluminum (Al), or an alloy of aluminum and copper. To prevent electromigration, the first top metal feature 224 and the second top metal feature 226 may be spaced apart from the first ESL 216, the second passivation layer 218 and the second ESL 220 by a first barrier layer 223 and a second barrier layer 225, respectively. The first barrier layer 223 and the second barrier layer 225 may include titanium nitride (TiN) or tantalum nitride (TaN). In the embodiments presented in FIG. 2, the first top metal feature 224 is configured to be coupled to a TSV extending through the guard ring structure 210 and the second top metal feature 226 is electrically coupled to a top metal line 212 of the interconnect structure 206 by multiple contact vias.

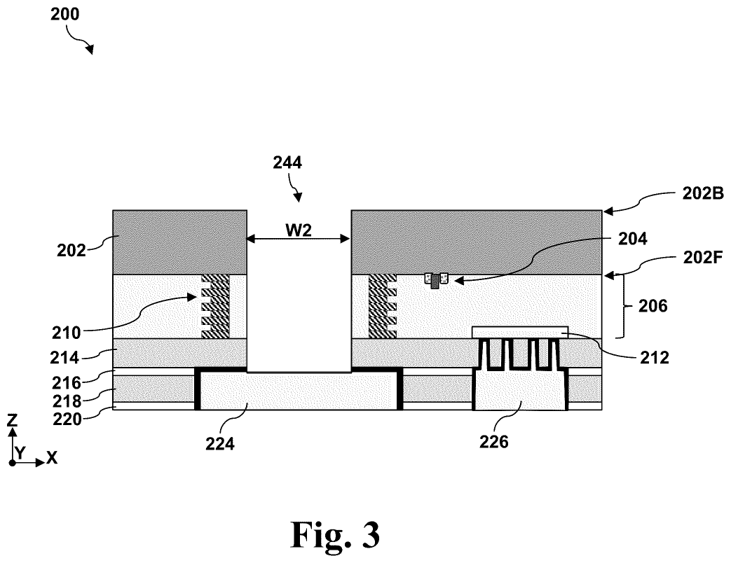

Referring to FIGS. 1, 2 and 3, method 100 includes a block 104 where a pilot opening 244 is formed through the substrate 202 and the interconnect structure 206. To form the pilot opening 244, a first masking layer 240 is formed over the back side 202B of the substrate 202. The first masking layer 240 may include a bottom antireflective coating (BARC) layer, a photoresist layer, silicon oxide, or silicon nitride. In one embodiment, the first masking layer 240 may be a photoresist layer having a thickness between about 5 μm and about 15 μm. The first masking layer 240 may be deposited using spin-on coating or flowable chemical vapor deposition (FCVD). The deposited first masking layer 240 then undergoes a pre-exposure baking process, exposure to radiation reflected from or transmitted through a photomask, a post-exposure baking process, and developing process, so as to form a first patterned mask 240. The first patterned mask 240 has a first opening 242. In some instances, the first opening 242 has a second width W2. When the first opening 242 is substantially circular in a top view, the second width W2 represents a diameter of the first opening 242. The first patterned mask 240 is then applied as an etch mask to etch the substrate 202, the interconnect structure 206, the first passivation layer 214, and the first barrier layer 223. The etch process for block 104 may be an anisotropic dry etch process (e.g., a reactive ion etching (RIE) process). In some instances, an example dry etch process may implement an oxygen-containing gas (e.g., O₂), a fluorine-containing gas (e.g., SF₆ or NF₃), a chlorine-containing gas (e.g., Cl₂ and/or BCl₃), a bromine-containing gas (e.g., HBr), an iodine-containing gas, other suitable gases and/or plasmas, and/or combinations thereof. The etching at block 104 terminates when the pilot opening 244 reaches a top surface of the first top metal feature 224. After the pilot opening 244 is formed, first patterned mask 240 is selectively removed by ashing or selective etching. In some instances, the pilot opening 244 shares the same second width W2 with the first opening 242. When the pilot opening 244 is substantially circular in a top view, the second width W2 represents a diameter of the pilot opening 244. As shown in FIG. 3, the pilot opening 244 vertically penetrates through the guard ring structure 210 and exposes a portion of the first top metal feature 224. To ensure that the pilot opening 244 penetrates through the guard ring structure 210, the second width W2 is smaller than the first width W1.

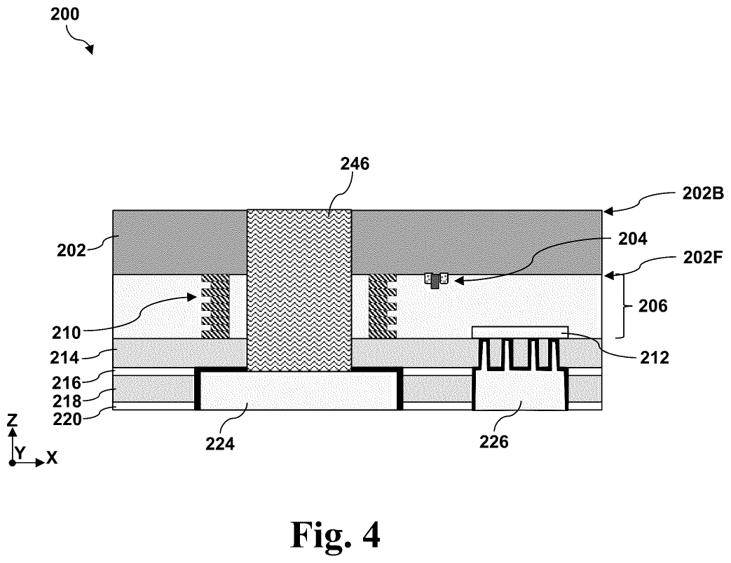

Referring to FIGS. 1 and 4, method 100 includes a block 106 where a sacrificial plug 246 is formed in the pilot opening 244. The sacrificial plug 246 is formed of organic polymer that includes carbon (C), hydrogen (H), oxygen (O), nitrogen (N), or a combination thereof. In some embodiments, the sacrificial plug 246 may include poly (methyl methacrylate) (PMMA), poly(methyl acrylate) (PMA), polymalcimide (PMAI), or a copolymer thereof. To form the sacrificial plug 246, a material for the sacrificial plug 246 is deposited over the WIP structure 200 and the pilot opening 244 by spin-on coating. After the deposited material is cured by exposure to ultraviolet (UV) radiation, exposure to water, or annealing, the cured material for the sacrificial plug 246 is etched back until the back side 202B of the substrate 202 is exposed, as shown in FIG. 4. At this point, the sacrificial plug 246 is formed in the pilot opening 244. The sacrificial plug 246 protects the first top metal feature 224 in a subsequent etching process.

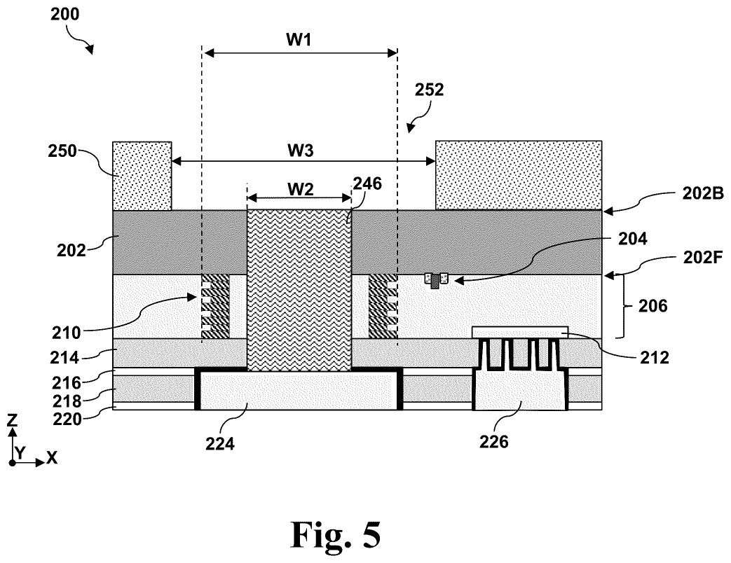

Referring to FIGS. 1 and 5, method 100 includes a block 108 where a second patterned mask 250 is formed over the WIP structure 200. To form the second patterned mask 250, a second masking layer 250 is deposited formed over the back side 202B of the substrate 202. The second masking layer 250 may include a bottom antireflective coating (BARC) layer, a photoresist layer, silicon oxide, or silicon nitride. In one embodiment, the second masking layer 250 may be a photoresist layer having a thickness between about 5 μm and about 15 μm. The second masking layer 250 may be deposited using spin-on coating or FCVD. The deposited second masking layer 250 then undergoes an pre-exposure baking process, exposure to radiation reflected from or transmitted through a photomask, a post-exposure baking process, and developing process, so as to form the second patterned mask 250 shown in FIG. 5. The second patterned mask 250 has a second opening 252. In some embodiments represented in FIG. 5, the second opening 252 has a third width W3. When the second opening 252 is substantially circular in a top view, the third width W3 represents a diameter of the second opening 252. The third width W3 is greater than the second width W2. In some instances, a ratio of the second width W2 to the third width W3 may be between about 1.1 and about 3. When the ratio of the second width W2 to the third width W3 is greater than 1.5, the second opening 252 may at least partially overlap an external profile of the guard ring structure 210.

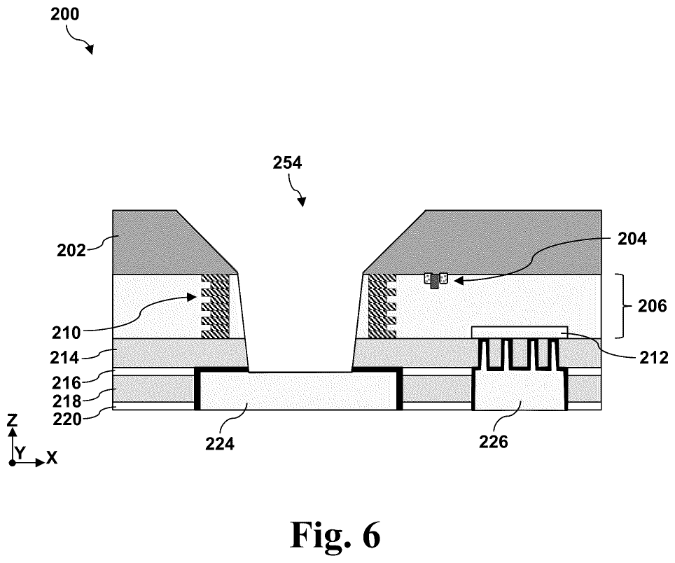

Referring to FIGS. 1 and 6, method 100 includes a block 110 where the substrate 202, the interconnect structure 206, and the sacrificial plug 246 are etched using the second patterned mask 250 as an etch mask to form a via opening 254. The second patterned mask 250 is then applied as an etch mask to etch the substrate 202, the interconnect structure 206, the sacrificial plug 246, the first passivation layer 214, and the first barrier layer 223. At block, the etch process includes an isotropic etch process. The isotropic etch process may be a wet isotropic etch process or a dry isotropic etch process. An example wet isotropic etch process may include use of dilute hydrofluoric acid (DHF), hydrogen peroxide (H₂O₂), ammonium hydroxide (NH₄OH), deionized water (H₂O), or a mixture thereof. An example dry isotropic etch process may include use of sulfur hexafluoride (SF₆) gas. The isotropic etch process at block 110 simultaneously widens the pilot opening 244 as it etches into the sacrificial plug 246, the IMD layers and the ESLs in the interconnect structure 206. As a result, the via opening 254 may include a first portion primarily below the substrate 202 and a second portion primarily in the substrate 202. Both the first portion and the second portion tapers downward in FIG. 6 toward the first top metal feature 224. The first portion includes a taper angle greater than that of the second portion. As shown in FIG. 6, the first portion of the via opening 254 remains surrounded by the guard ring structure 210. The second portion of the via opening 254 may extend directly over at least a portion of the guard ring structure 210. After the via opening 254 is formed, the second patterned mask 250 is selectively removed by ashing or selective etching. Because the via opening 254 includes the first portion and the second portion of different widths, the via opening 254 may be referred to as a dual-damascene opening.

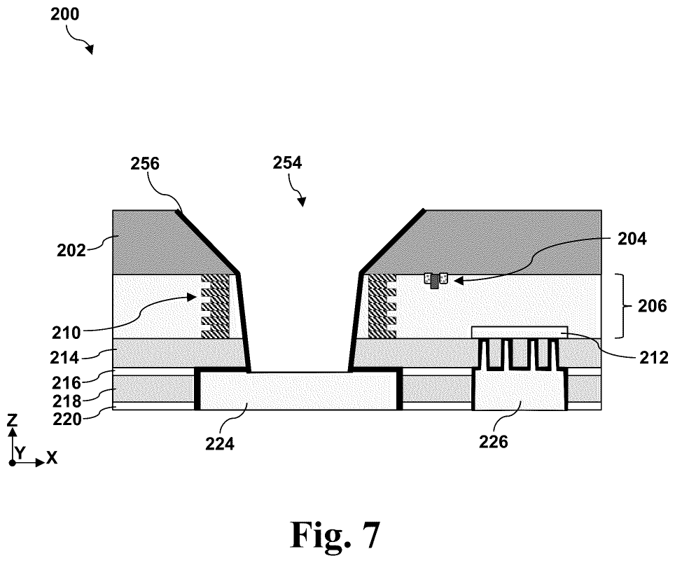

Referring to FIGS. 1 and 7, method 100 includes a block 112 where a dielectric liner 256 is deposited over the WIP structure 200 and the via opening 254. In some embodiments, the dielectric liner 256 includes silicon nitride or silicon oxide. In an example process, a material layer for the dielectric liner 256 is first deposited over the WIP structure 200 and the via opening 254 by atomic layer deposition (ALD) or CVD. In one embodiment, the material layer is deposited using ALD. An anisotropic etch back process is then performed to remove the material layer on the top-facing surfaces of the substrate 202 and the first top metal feature 224, so as to form the dielectric liner 256 shown in FIG. 7. The dielectric liner 256 covers sidewalls of the via opening 254. The anisotropic etch process at block 112 may include use of an oxygen-containing gas (e.g., O₂), a fluorine-containing gas (e.g., SF₆ or NF₃), a chlorine-containing gas (e.g., Cl₂ and/or BCl₃), a bromine-containing gas (e.g., HBr), an iodine-containing gas, other suitable gases and/or plasmas, and/or combinations thereof.

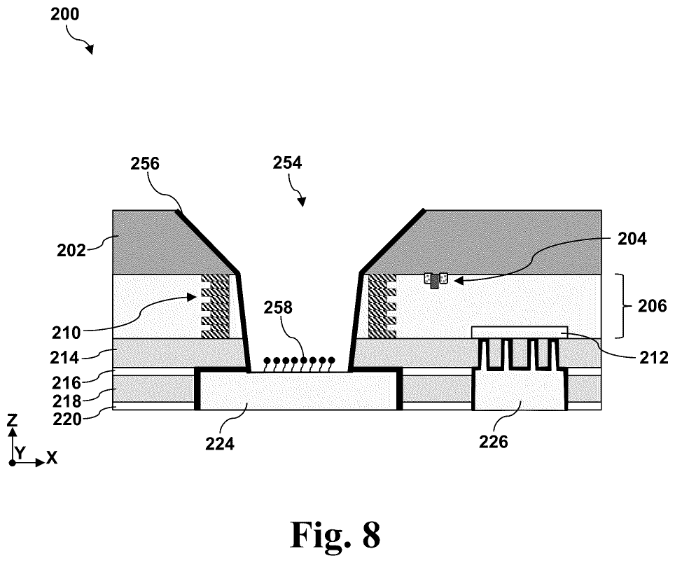

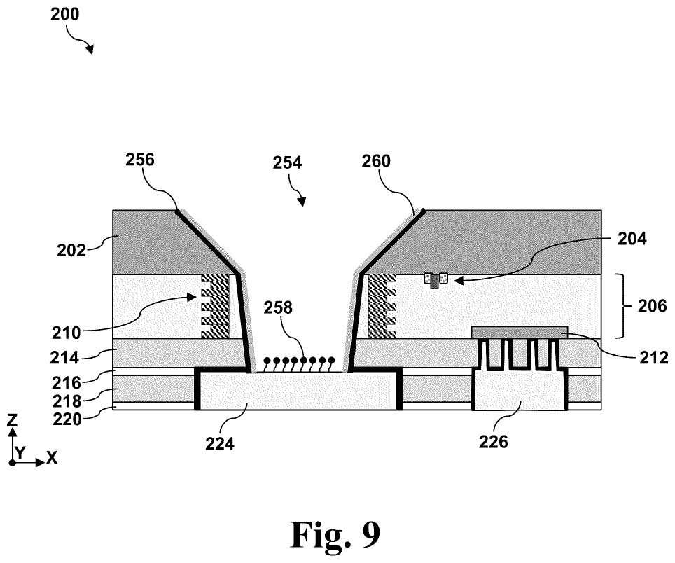

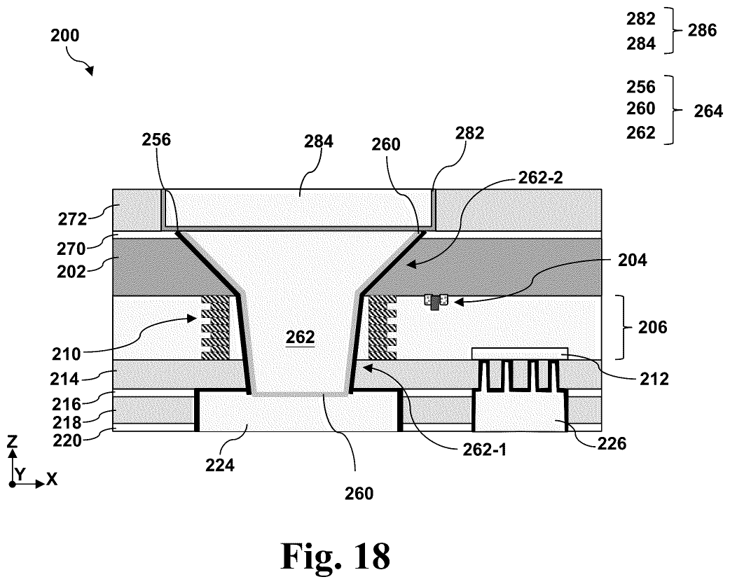

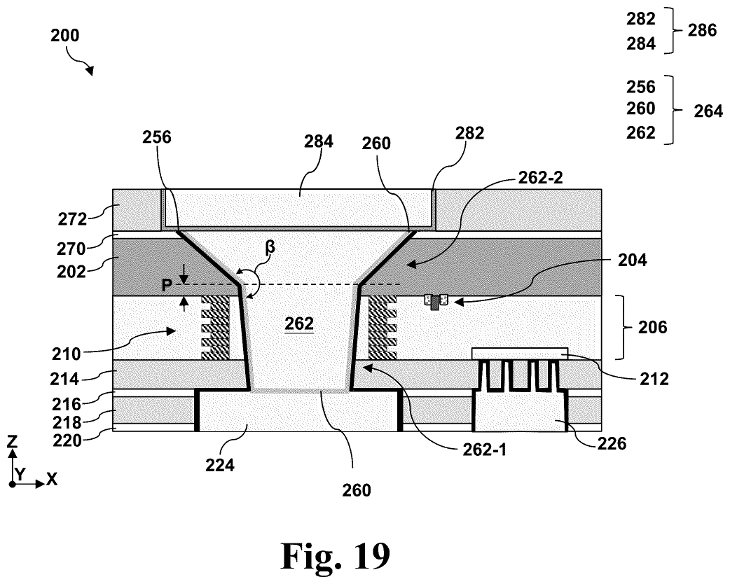

Referring to FIGS. 1 and 8-10, method 100 includes a block 114 where a barrier layer 260 is deposited the dielectric liner 256. In some embodiments represented in FIGS. 8-10, the barrier layer 260 is not deposited to cover the first top metal feature 224. To achieve that, a self-assemble monolayer (SAM) 258 is selectively deposited on the exposed surface of the first top metal feature 224, as shown in FIG. 8. In one embodiment, the SAM 258 may include tetrakis (dimethylamino) titanium (TDMAT). In some alternative embodiments, the SAM 258 may be formed of a molecule that includes a head group (or anchor) and a tail group. In some instances, the head group may include phosphorus (P), sulfur(S), or silicon (Si), which in some cases may be in the form of phosphate, sulfate, or silane based substances. The tail group may include a carbon chain, such as one including alkenes and alkynes. In some examples, the molecule forming the SAM 258 (or the head group of the molecule for the SAM 258) may include ODPA (Octadecylphosphonic acid), organosulfurs, or thiols (e.g., dodecanethiol, alkanethiol). In some other implementations, the molecule forming the SAM 258 may include (3-aminopropyl) tricthoxysilane (APTES). In some instances, the SAM 258 is attachable to a conductive layer, such as the first top metal feature 224 but does not substantially attach to the surfaces of the substrate 202 or the dielectric liner 256, which is formed a semiconductor material or a dielectric material. Referring to FIG. 9, after the SAM 258 is deposited to cover the first top metal feature 224, the barrier layer 260 is deposited over the WIP structure 200. Because precursors of the barrier layer 260 have low affinity to the SAM 258 (i.e. the SAM 258 repels the precursors of the barrier layer 260), the SAM 258 functions as a blocking layer or a hinderance layer for the barrier layer 260. In some embodiments, the barrier layer 260 may include tantalum nitride (TaN), titanium nitride (TiN), tungsten nitride (WN), or combinations thereof. In some alternative embodiments, the SAM 258 is not deposited over the first top metal feature 224 and the barrier layer 260 is deposited over the top surface of the first top metal feature 224, as shown in FIGS. 18 and 19.

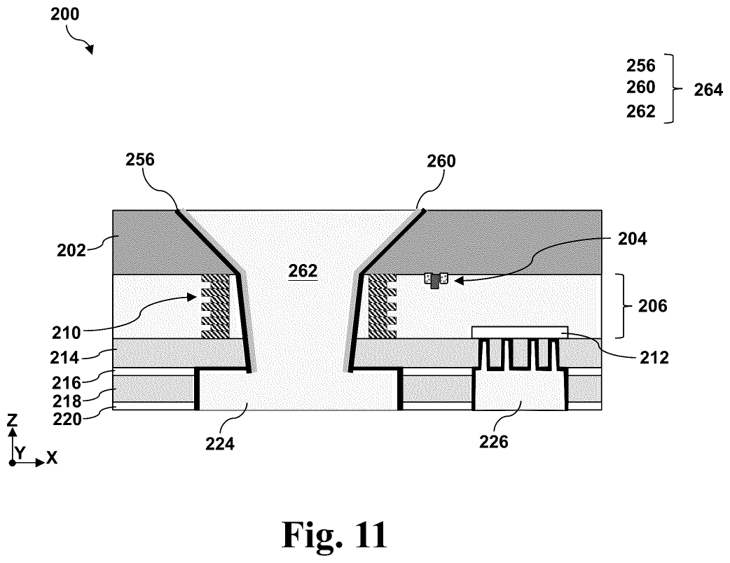

Referring to FIGS. 1 and 11, method 100 includes a block 116 where a metal fill layer 262 over the via opening 254. The metal fill layer 262 may include copper (Cu), aluminum (Al), cobalt (Co), copper alloy, tantalum (Ta), titanium (Ti), or tungsten (W). In one embodiment, the barrier layer 260 includes titanium nitride (TiN) and the metal fill layer 262 includes copper (Cu). The metal fill layer 262 is deposited using electroplating, physical vapor deposition (PVD), CVD, electroless plating, or a suitable method. In one embodiment, the metal fill layer 262 is formed using electroplating. In this embodiment, after the formation of the barrier layer 260, a seed layer (not shown) may be deposited, using PVD or a suitable process, over the WIP structure 200, including over surfaces of the barrier layer 260. Then the metal fill layer 262 may be deposited over the seed layer using electroplating. In the embodiment where electroplating is used, the seed layer may include copper (Cu), titanium (Ti), or a combination thereof and the metal fill may include copper (Cu). The seed layer may be considered part of the metal fill layer 262. After the metal fill layer 262 is deposited over the WIP structure 200 and into the via opening 254, a planarization process, such as a CMP, may be performed to provide a substantial coplanar top surface. As shown in FIG. 11, the planarization process may etch the substrate 202 at a higher rate such that the metal fill layer 262 and the barrier layer 260 rises above a top surface of the substrate 202. At this point, a via structure 264 is formed. The via structure 264 includes the dielectric liner 256, the barrier layer 260 and the metal filler layer 262. The via structure 264 may be referred to as a dual-damascene via structure.

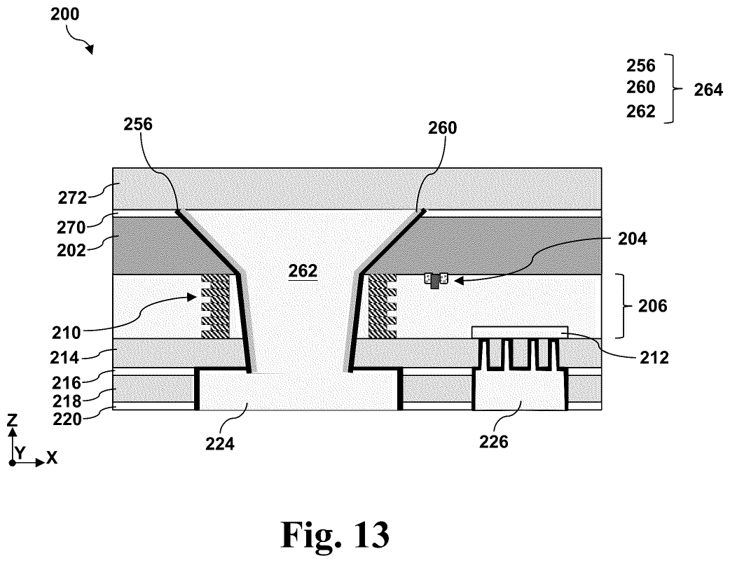

Referring to FIGS. 1, 12 and 13, method 100 includes a block 118 where an etch stop layer (ESL) 270 is formed over the substrate 202. At block 118, the ESL 270 is deposited over the WIP structure 200 by ALD or CVD. After the deposition of the ESL 270, the WIP structure 200, is planarized such that top surfaces of the via structure 264 and the ESL 270 are coplanar, as shown in FIG. 13. Because the via structure 264 rises above the top surface of the substrate 202. The top surface of the substrate 202 remains covered by the ESL 270. The planarization at block 118 may include a chemical mechanical polishing (CMP) process.

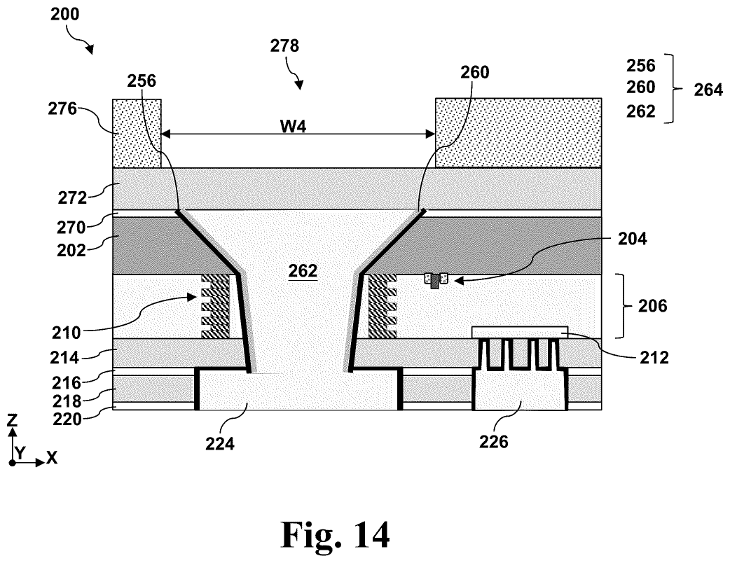

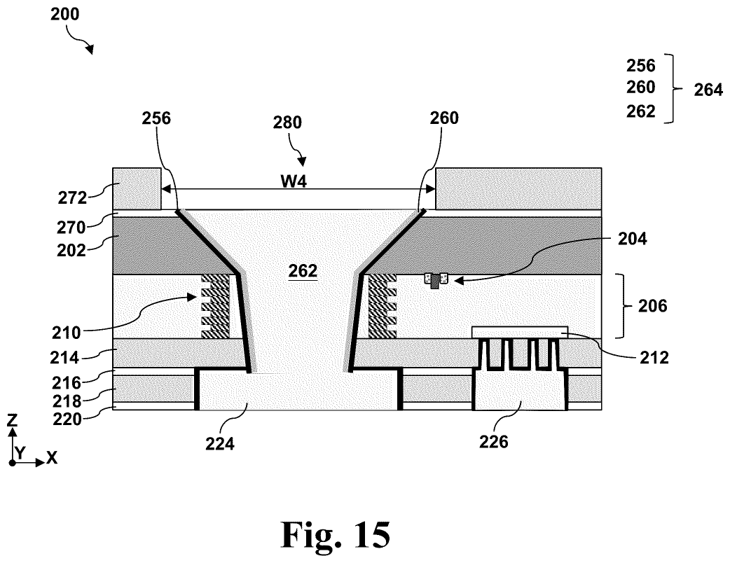

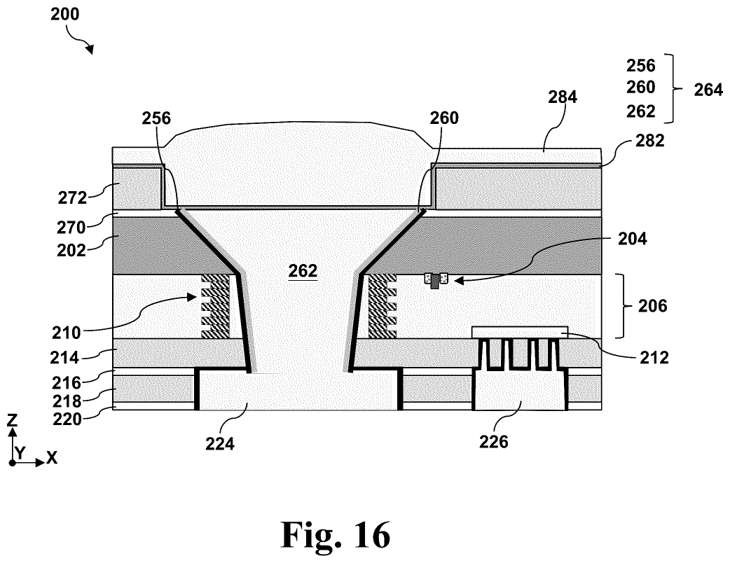

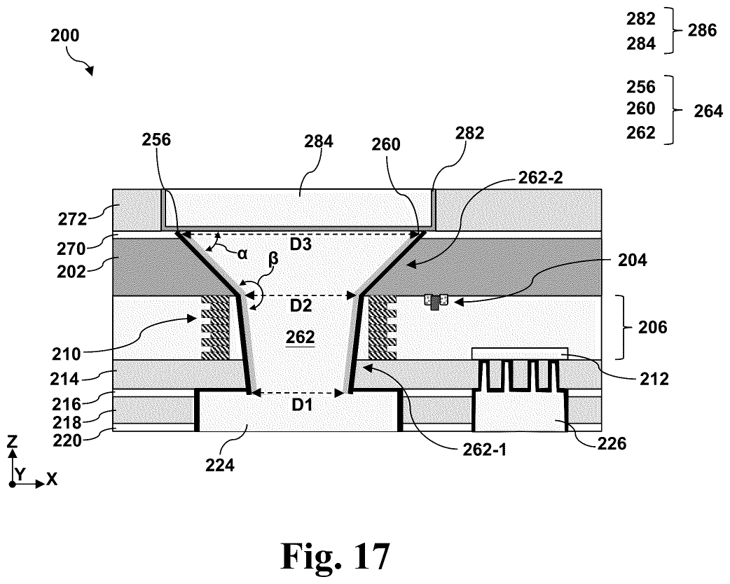

Referring to FIGS. 1 and 13-20, method 100 includes a block 120 where further processes are performed. Such further processes may include deposition of a backside dielectric layer 272 (shown in FIG. 13), patterning of the backside dielectric layer 272 to form a contact opening 280 (shown in FIGS. 14 and 15), and forming a contact feature 286 in the contact opening 280 (shown in FIGS. 16 and 17). Referring to FIG. 13, after the planarization at block 118, the backside dielectric layer 272 is deposited over the top surfaces of the via structure 264 and the substrate 202. The backside dielectric layer 272 may include silicon oxide, tetraethylorthosilicate (TEOS) oxide, un-doped silicate glass (USG), or doped silicon oxide such as borophosphosilicate glass (BPSG), fused silicate glass (FSG), phosphosilicate glass (PSG), boron doped silicate glass (BSG), low-k dielectric material, other suitable dielectric material, or combinations thereof. In some implementations, the backside dielectric layer 272 may be deposited using spin-on coating, FCVD, or CVD.

Reference is now made to FIG. 14. A third patterned mask 276 is formed over the backside dielectric layer 272. The third patterned mask 276 includes a third opening 278 to expose a portion of the backside dielectric layer 272. To form the third patterned mask 276, a third masking layer 276 is deposited over the backside dielectric layer 272. The third masking layer 276 may include a bottom antireflective coating (BARC) layer, a photoresist layer, silicon oxide, or silicon nitride. In one embodiment, the third masking layer 276 may be a photoresist layer having a thickness between about 5 μm and about 15 μm. The third masking layer 276 may be deposited using spin-on coating or FCVD. The deposited third masking layer 276 then undergoes an pre-exposure baking process, exposure to radiation reflected from or transmitted through a photomask, a post-exposure baking process, and developing process, so as to form the third patterned mask 276 shown in FIG. 14. The third patterned mask 276 has the third opening 278. In some embodiments represented in FIG. 14, the third opening 278 has a fourth width W4. When the third opening 278 is substantially circular in a top view, the fourth width W4 represents a diameter of the third opening 278. The fourth width W4 is greater than the third width W3 to ensure that the via structure 264 lands completely on the contact feature to be formed in an opening formed using the third opening 278. Referring to FIG. 15. The third pattern mask 276 is applied as an etch mask to etch the backside dielectric layer 272 to form the contact opening 280. The etch process to form the contact opening 280 may include use of an oxygen-containing gas (e.g., O₂), a fluorine-containing gas (e.g., SF₆ or NF₃), a chlorine-containing gas (e.g., Cl₂ and/or BCl₃), a bromine-containing gas (e.g., HBr), an iodine-containing gas, other suitable gases and/or plasmas, and/or combinations thereof. The contact opening 280 may also has the fourth width W4 as does the third opening 278.

Reference is now made to FIGS. 16 and 17. A barrier layer 282 is deposited over the WIP structure 200, including over the contact opening 280. The barrier layer 282 may include titanium nitride (TiN) or tantalum nitride (TaN) and may be deposited using CVD or metalorganic CVD (MOCVD). After the deposition of the barrier layer 282, a seed layer (not explicitly shown in the figures) is deposited using PVD. The seed layer may include titanium (Ti) or copper (Cu). Electrochemical plating (ECP) is then used to deposit a metal fill 284 over the barrier layer 282. The metal fill 284 may include copper (Cu), aluminum (Al), or an alloy of aluminum and copper. In some implementations, the metal fill 284 over contact opening 280 may be thicker, as shown in FIG. 16. Referring to FIG. 17, a planarization process, such as a CMP process, is performed to remove excess materials. At this point, a contact feature 286 is formed. The contact feature 286 includes the barrier layer 282 and the metal fill layer 284.

As illustrated in FIG. 17, the via structure 264 includes a first portion 262-1 disposed substantially in the interconnect structure 206 and the first passivation layer 214 and a second portion 262-2 disposed substantially in the substrate 202. Th via structure 264 includes a first dimension D1 at its interface with the first top metal feature 224, a second dimension D2 at an interface between the first portion 262-1 and the second portion 262-2, and a third dimension D3 at an interface between the via structure 264 an the contact feature 286. In some instances, the third dimension D3 is between about 2 μm and about 4 μm. In some implementations, the second dimension D2 is greater than or equal to the first dimension D1 and the third dimension D3 is greater than or equal to the second dimension D2. The via structure 264 has a footing angle α with a top surface of the top metal feature 224. The via structure 264 also has a transition angle β across the interface between the first portion 262-1 and the second portion 262-2. A ratio of the second dimension D2 to the first dimension D1 may be between 1.05 and 1.25. A ratio of the third dimension D3 to the second dimension D2 may be between about 1 and 3. In some implementations, the footing angle α may be between about 70° and about 90°. That is, the footing angle α is an acute angle. The transition angle β may be between about 180° and about 200°. That is, the transition angle β is greater than a straight angle (i.e., 180°). In some instances, an aspect ratio of the via structure 264 may be between about 5 and about 15. In some embodiments represented in FIG. 17, the interface between the first portion 262-1 and the second portion 262-2 is at the interface between the interconnect structure 206 and the substrate 202. Due to use of the SAM 258 at block 114, the barrier layer 260 does not extend between the first top metal feature 224 and the via structure 264. In some embodiments represented in FIG. 17, the first portion 262-1 widens away from the interface between the first portion 262-1 and the second portion 262-2 so much so that the first portion 262-1 overhangs a portion or an entirety of the guard ring structure 210. That is, along the Z direction, a vertical projection area of the first portion 262-1 partially or completely overlaps with a vertical projection area of the guard ring structure 210.

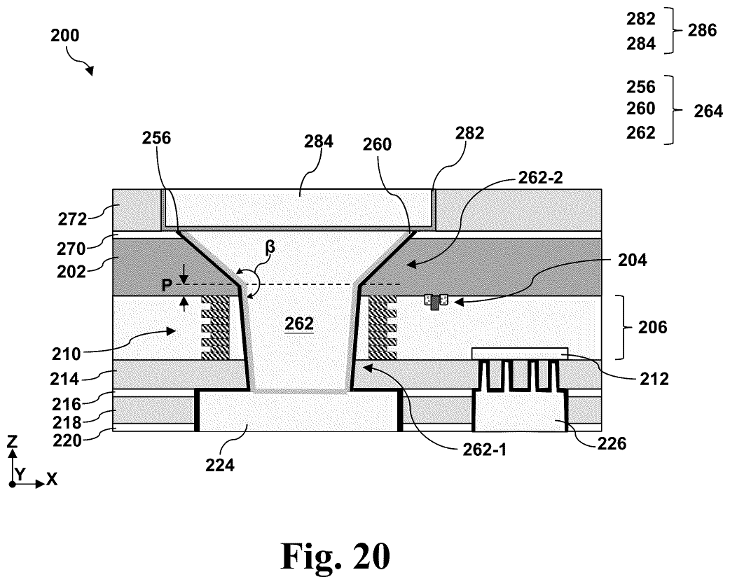

FIGS. 18-20 illustrate example alternative embodiments. FIG. 18 illustrates an embodiment where the SAM 258 is not deposited to block the first top metal feature 224. As a result, the barrier layer 260 extends between the first top metal feature 224 and the via structure 264. FIG. 19 illustrates an embodiments where the interface between the first portion 262-1 and the second portion 262-2 moves away from the interconnect structure 206 and is situated completely in the substrate 202. FIG. 20 illustrates an embodiment where the SAM 258 is not deposited to block the first top metal feature 224 and the interface between the first portion 262-1 and the second portion 262-2 moves away from the interconnect structure 206. According to the present disclosure, the interface between the first portion 262-1 and the second portion 262-2 should be either at the interface between the interconnect structure 206 and the substrate 202 or completely disposed in the substrate 202 to prevent damages to or interference with front-end-of-line (FEOL) devices.

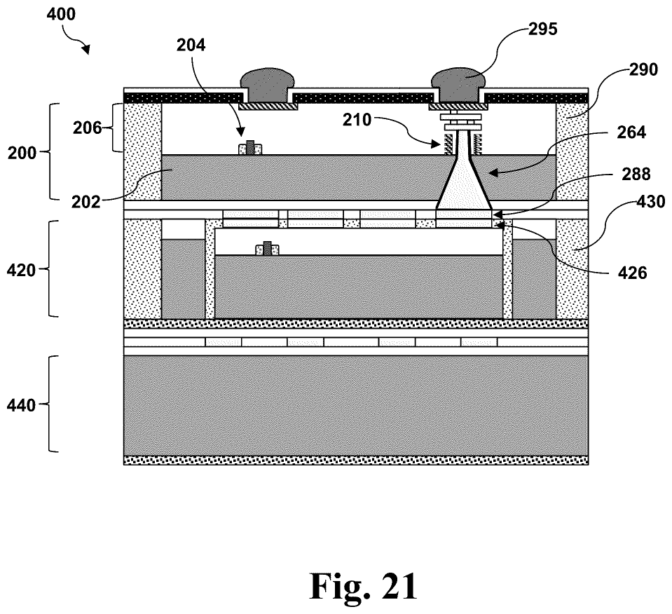

FIG. 21 is a fragmentary cross-sectional view of IC device package 400 that includes the die 200. The die 200, which is formed from the WIP structure 200, includes the substrate 202 and the interconnect structure 206. Transistor 204 (one shown for representation) are formed over the substrate 202. The die 200 may be surrounded and protected by a molding material 290. The die 200 is bonded to a die 420 by direct bonding. Bonding pads on the die 200, such as bonding pad 288, are aligned with and bonded to bonding pads on the die 420, such ss bonding pad 426. The dielectric layer around the bonding pads on the dies 200 and 420 are also in contact and bonded together. The die 420 is bonded to a die 440 by direct bonding. The die 420 is surrounded by a molding material 430. The die 200 includes solder features 295 to interface a package substrate, an interposer, or a printed circuit board (PCB) substrate. The via structure 264 includes a first portion (262-1 in FIG. 17) disposed in the interconnect structure 206 and a second portion (262-2 in FIG. 17) disposed in the substrate 202. The second portion tapers toward the interconnect structure 206. The first portion is surrounded by the guard ring structure 210. An interface between the first portion and the second portion is either at the interface between the substrate 202 and the interconnect structure 206 or in the substrate 202. The solder feature 295 is closer to the first portion than the second portion.

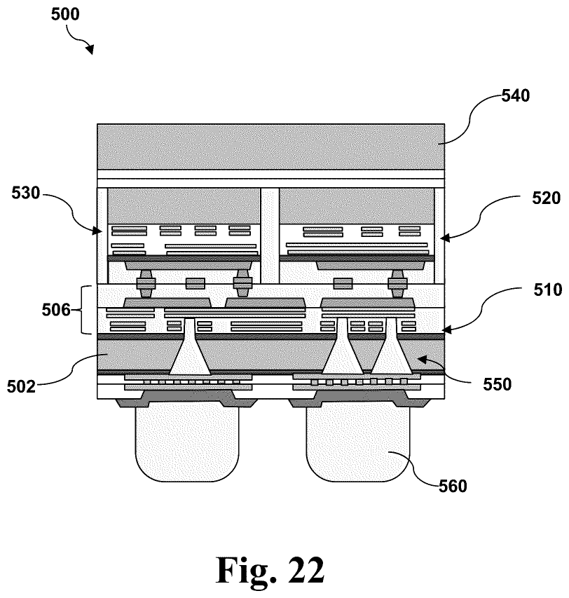

FIG. 22 is a fragmentary cross-sectional view of IC device package 500 that includes a die 510 bonded to a die 520 and a die 530. The dies 520 and 530 are disposed side-by-side and are bonded to a carrier substrate 540. The die 510 includes a substrate 502 and an interconnect structure 506 disposed on the substrate 202. The die 510 includes via structures 550 that extends through the substrate 502 and a portion of the interconnect structure 506. Each of the via structures 550 includes a first portion disposed in the interconnect structure 506 and a second portion disposed in the substrate 502. The first portion is surrounded by guard rings similar to the guard ring structure 210 shown in FIG. 17. The second portion tapers toward the interconnect structure 506. An interface between the first portion and the second portion is either at the interface between the substrate 502 and the interconnect structure 506 or in the substrate 502. The die 510 includes solder features 560, which may be micro-bumps. Different from the via structure 264 in FIG. 21, the second portion is more adjacent to the solder features 560 than the first portion.

In one exemplary aspect, the present disclosure is directed to a structure. The structure includes a bottom metal feature, a semiconductor substrate disposed over the bottom metal feature, an interconnect structure disposed over the semiconductor substrate, a top metal feature over the interconnect structure, and a via structure extending from a bottom surface of the top metal feature, through the interconnect structure and the semiconductor substrate, to contact a top surface of the bottom metal feature. The via structure includes a bottom portion disposed in the semiconductor substrate and a top portion disposed in the interconnect structure. The bottom portion and the top portion taper toward the top metal feature. The bottom portion includes a first tapering angle and the top portion includes a second tapering angle smaller than the first tapering angle.

In some embodiments, the structure further includes an etch stop layer (ESL) disposed between the semiconductor substrate and the bottom metal feature. A bottom surface of the bottom metal feature is coplanar to a bottom surface of the ESL. In some embodiments, the bottom portion of the via structure is disposed completely below the interconnect structure. In some implementations, the via structure is spaced apart from the semiconductor substrate and the interconnect structure by a dielectric liner. In some instances, the dielectric liner includes silicon oxide, silicon nitride, or a combination thereof. In some embodiments, the structure further includes a barrier layer sandwiched between the via structure and the dielectric liner. In some embodiments, the barrier layer includes titanium, tantalum, tantalum nitride, or titanium nitride.

In another exemplary aspect, the present disclosure is directed to a contact structure. The contact structure includes a dielectric layer, a top metal feature disposed in the dielectric layer, an interconnect structure disposed over the dielectric layer and the top metal feature, the interconnect structure including a guard ring structure, a substrate over the interconnect structure, and a via structure extending through the substrate and the interconnect structure to contact the top metal feature. The via structure includes a bottom portion surrounded by the guard ring structure and a top portion disposed over the bottom portion. The top portion overhangs the guard ring structure.

In some embodiments, the bottom portion and the top portion taper toward the top metal feature and the bottom portion includes a first tapering angle and the top portion includes a second tapering angle greater than the first tapering angle. In some implementations, the contact structure further includes an etch stop layer (ESL) over the substrate and top surfaces of the via structure and the ESL are coplanar. In some embodiments, the contact structure further includes a barrier layer sandwiched between the ESL and the via structure.

In yet another exemplary aspect, the present disclosure is directed to a method. The method includes providing an intermediate structure that includes a metal feature disposed in a dielectric layer, an interconnect structure disposed over the metal feature and the dielectric layer, and a substrate disposed over the interconnect structure, forming a pilot opening through the substrate and the interconnect structure to expose a top surface of the metal feature, depositing a polymer plug in the pilot opening, forming a patterned hard mask over the intermediate structure and the polymer plug, the patterned hard mask including a pattern opening that encloses the polymer plug, etching the substrate, the polymer plug, and the interconnect structure using the patterned hard mask as an etch mask to form a via opening to expose the metal feature, forming a dielectric liner over sidewalls of the via opening, depositing a barrier layer over the dielectric liner, depositing a metal plug over the barrier layer, depositing an etch stop layer (ESL) over the metal plug and the substrate, and planarizing the ESL until top surfaces of the ESL and the metal plug are coplanar.

In some embodiments, the interconnect structure includes a guard ring structure and the pilot opening extends through the guard ring structure. In some embodiments, a portion of the metal plug overhangs the guard ring structure. In some implementations, the polymer plug, and the interconnect structure includes use of an isotropic etch process. In some embodiments, the isotropic etch process is a wet etch process that includes use of dilute hydrofluoric acid (DHF), hydrogen peroxide (H₂O₂), ammonium hydroxide (NH₄OH), deionized water (H₂O), or a mixture thereof. In some embodiments, the isotropic etch process is a dry etch process that inculdes use of sulfur hexafluoride (SF₆) gas. In some instances, the forming of the dielectric liner includes use of atomic layer deposition (ALD). In some embodiments, the method further includes after the forming of the dielectric liner, anisotropically etching the intermediate structure to expose the metal feature, and before the depositing of the barrier layer, depositing a self-assembled monolayer (SAM) layer over the exposed metal feature. The SAM layer prevent deposition of the barrier layer over the metal feature. In some embodiments, the method further includes after the depositing of the barrier layer, removing the SAM layer to expose the metal feature.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A structure, comprising:
a bottom metal feature;
a semiconductor substrate disposed over the bottom metal feature;
an interconnect structure disposed over the semiconductor substrate;
a top metal feature over the interconnect structure; and
a via structure extending from a bottom surface of the top metal feature, through the interconnect structure and the semiconductor substrate, to contact a top surface of the bottom metal feature,
wherein the via structure comprises a bottom portion disposed in the semiconductor substrate and a top portion disposed in the interconnect structure,
wherein the bottom portion and the top portion taper toward the top metal feature,
wherein the bottom portion comprises a first tapering angle and the top portion comprises a second tapering angle smaller than the first tapering angle.

2. The structure of claim 1, further comprising:
an etch stop layer (ESL) disposed between the semiconductor substrate and the bottom metal feature,
wherein a bottom surface of the bottom metal feature is coplanar to a bottom surface of the ESL.

3. The structure of claim 2, wherein the bottom portion of the via structure is disposed completely below the interconnect structure.

4. The structure of claim 2, wherein the via structure is spaced apart from the semiconductor substrate and the interconnect structure by a dielectric liner.

5. The structure of claim 4, wherein the dielectric liner comprises silicon oxide, silicon nitride, or a combination thereof.

6. The structure of claim 4, further comprising:
a barrier layer sandwiched between the via structure and the dielectric liner.

7. The structure of claim 6, wherein the barrier layer comprises titanium, tantalum, tantalum nitride, or titanium nitride.

8. A contact structure, comprising:
a dielectric layer;
a top metal feature disposed in the dielectric layer;
an interconnect structure disposed over the dielectric layer and the top metal feature, the interconnect structure comprising a guard ring structure;
a substrate over the interconnect structure; and
a via structure extending through the substrate and the interconnect structure to contact the top metal feature,
wherein the via structure comprises a bottom portion surrounded by the guard ring structure and a top portion disposed over the bottom portion,
wherein the top portion overhangs the guard ring structure.

9. The contact structure of claim 8,
wherein the bottom portion and the top portion taper toward the top metal feature,
wherein the bottom portion comprises a first tapering angle and the top portion comprises a second tapering angle greater than the first tapering angle.

10. The contact structure of claim 8, further comprising:
an etch stop layer (ESL) over the substrate,
wherein top surfaces of the via structure and the ESL are coplanar.

11. The contact structure of claim 10, further comprising:
a barrier layer sandwiched between the ESL and the via structure.

12. A method, comprising:
providing an intermediate structure comprising:
a metal feature disposed in a dielectric layer,
an interconnect structure disposed over the metal feature and the dielectric layer, and
a substrate disposed over the interconnect structure;
forming a pilot opening through the substrate and the interconnect structure to expose a top surface of the metal feature;
depositing a polymer plug in the pilot opening;
forming a patterned hard mask over the intermediate structure and the polymer plug, the patterned hard mask comprising a pattern opening that encloses the polymer plug;
etching the substrate, the polymer plug, and the interconnect structure using the patterned hard mask as an etch mask to form a via opening to expose the metal feature;
forming a dielectric liner over sidewalls of the via opening;
depositing a barrier layer over the dielectric liner;
depositing a metal plug over the barrier layer;
depositing an etch stop layer (ESL) over the metal plug and the substrate; and
planarizing the ESL until top surfaces of the ESL and the metal plug are coplanar.

13. The method of claim 12,
wherein the interconnect structure comprises a guard ring structure,
wherein the pilot opening extends through the guard ring structure.

14. The method of claim 13, wherein a portion of the metal plug overhangs the guard ring structure.

15. The method of claim 12, wherein the etching of the substrate, the polymer plug, and the interconnect structure comprises use of an isotropic etch process.

16. The method of claim 15, wherein the isotropic etch process is a wet etch process that comprises use of dilute hydrofluoric acid (DHF), hydrogen peroxide (H₂O₂), ammonium hydroxide (NH₄OH), deionized water (H₂O), or a mixture thereof.

17. The method of claim 15, wherein the isotropic etch process is a dry etch process that comprises use of sulfur hexafluoride (SF₆) gas.

18. The method of claim 12, wherein the forming of the dielectric liner comprises use of atomic layer deposition (ALD).

19. The method of claim 12, further comprising:
after the forming of the dielectric liner, anisotropically etching the intermediate structure to expose the metal feature; and
before the depositing of the barrier layer, depositing a self-assembled monolayer (SAM) layer over the exposed metal feature,
wherein the SAM layer prevent deposition of the barrier layer over the metal feature.

20. The method of claim 19, further comprising:
after the depositing of the barrier layer, removing the SAM layer to expose the metal feature.
